(19) United States
(12) Patent Application Publication
(10) Pub. No.: US 2005/0110066 A1
(43) Pub. Date: May 26, 2005

(54) Deep trench structure and memory device having the same

(75) Inventor: Ming-Cheng Chang, Taoyuan (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/718,666

(22) Filed: Nov. 24, 2003

(51) Int. Cl. H01L 27/108

(52) U.S. Cl. 257/301

(57) ABSTRACT

Disclosed is a deep trench structure for a semiconductor memory device. The deep trench in accordance with the present invention has a cross section communicating with two difference active areas, which are respectively connected to two adjacent bit lines of the semiconductor memory device.

### BACKGROUND OF THE INVENTION

1. Field of the Invention

The present invention relates to a semiconductor memory device, more specifically, to a deep trench structure facilitating electrical test.

2. Description of the Prior Art

In semiconductor technology, testing technique is used to detect the defects and bugs in the wafers in order to find out defective products and promote the throughput. The electrical test for the semiconductor memory device is very important. The electrical parameters of the memory device directly influence the function and performance of the memory.

In the current techniques for semiconductor memory devices, deep trench technique is generally used in a semiconductor memory device structure having compact memory cell array. Because of the buried straps in the structure, it is impossible to directly access the deep trench capacitor. Accordingly, it is difficult to measure the leakages at the buried strap side such as gate inducing drain leakage (GIDL) and junction leakage.

Therefore, there is a need for a solution to overcome the problems stated above. The present invention satisfies such a need.

### SUMMARY OF THE INVENTION

An objective of the present invention is to provide a deep trench structure of semiconductor device, which facilitates the measurement of the leakage currents.

Another objective of the present invention is to provide a semiconductor memory device, in which the leakage currents are easy to measure.

According to an aspect of the present invention, a deep trench structure of semiconductor device is characterized in that the cross section of the deep trench communicates with two different active areas of the semiconductor device.

According to another aspect of the present invention, a semiconductor memory device comprises a plurality of bit lines; a plurality of gates crossing with said bit lines; a plurality of active areas, each of which is connected with one of said bit lines; and a plurality of deep trenches, at least one of which has a cross section communicating with two different active areas.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIG. 1 shows a schematic diagram of the top view of a portion of a semiconductor memory device having a deep trench structure in accordance with the present invention; and

FIG. 2 shows the longitudinal sectional diagram taken from the path A-A in FIG. 1.

### DETIALED DESCRIPTION OF THE PREFERRED EMBODIMENT

An embodiment of the present invention will be described in detail with reference to the accompanying drawings.

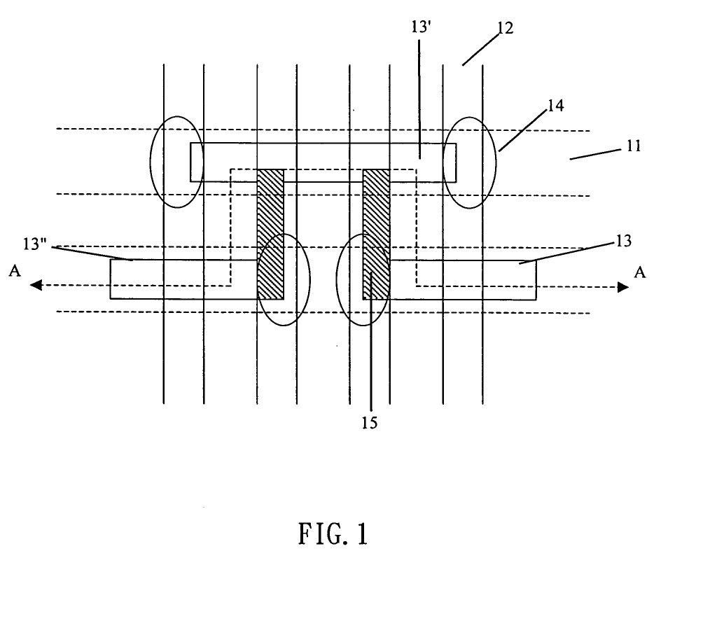

With reference to FIG. 1, it is a schematic diagram showing a top view of a portion of a semiconductor memory device having deep trenches in accordance with the present invention. Reference number 11 indicates a bit line, 12 indicates a gate crossing with said bit line, and the bit lines 11 and gates 12 constitute an array arrangement. Reference numbers 13, 13′ and 13″ indicate active areas connected with the bit lines, 14 indicates a conventional deep trench, while 15 indicates a deep trench in accordance with the present invention.

As shown in the drawing, the cross sections of the deep trenches 15 are lengthened, so that the two deep trenches 15 respectively communicate with active areas 13 and 13′, as well as active areas 13″ and 13′ connected with adjacent bit lines. By means of such a structure, GIDL current and junction leakage current can be easily measured through the gate 12.

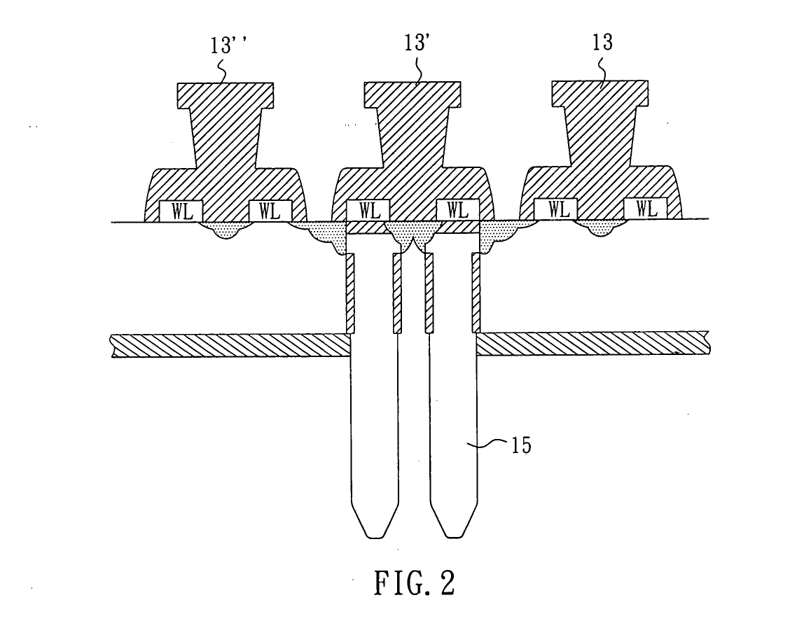

FIG. 2 shows a schematic longitudinal sectional diagram taken from the path A-A in FIG. 1 for reference, wherein WL indicates a word line.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A deep trench structure of semiconductor device, said semiconductor device having a plurality of active areas, said deep trench structure characterized in that said deep trench communicates with two different active areas.

2. The structure as claimed in claim 1, wherein the cross section of said deep trench communicates with two different active areas.

3. The structure as claimed in claim 2, wherein said two different active areas communicated by said deep trench are respectively connected with two adjacent bit lines.

4. A semiconductor memory device comprising:
a plurality of bit lines;
a plurality of gates crossing with said bit lines;
a plurality of active areas, each of which is connected to one of said bit lines;
a plurality of deep trenches, at least one of which communicates with two different active areas.

5. The device as claimed in claim 4, wherein the cross section of said deep trench communicates with two different active areas.

6. The device as claimed in claim 5, wherein said two different active areas communicated by said deep trench are respectively connected with two adjacent bit lines.
